(19) United States
(12) Patent Application Publication
(10) Pub. No.: US 2010/0330301 A1
(43) Pub. Date: Dec. 30, 2010

(54) APPARATUS AND METHOD FOR PROCESSING SUBSTRATE

(75) Inventor: Il-Kwang Yang, Yongin-si (KR)

Correspondence Address: LRK Patent Law Firm, 1952 Gallows Rd, Suite 200, Vienna, VA, 22182, US

(73) Assignee: EUGENE TECHNOLOGY CO., LTD., Yongin-si (KR)

(21) Appl. No.: 12/867,762

(22) PCT Filed: Feb. 20, 2009
(86) PCT No.: PCT/KR09/00809

§ 371 Date: Aug. 16, 2010

(30) Foreign Application Priority Data
Feb. 22, 2008 (KR) 10-2008-0016138

(51) Int. Cl. C23C 16/44; C23C 16/513; C23C 16/22

(52) U.S. Cl. 427/578; 118/723 R; 427/569

(57) ABSTRACT

A substrate processing apparatus includes a chamber defining a process space where a process is carried out with respect to a substrate, a first supply member located above the process space for supplying a first source gas toward the process space, a plasma source configured to generate an electric field in the process space to create radicals from the first source gas, and a second supply member configured to supply a second source gas above the substrate. The chamber includes a lower chamber in which a support member configured to allow the substrate to be placed thereon is installed. The lower chamber is open at a top thereof. The second supply member is installed at an upper end of the lower chamber for supplying the second source gas in a direction generally parallel to the substrate placed on the support member. The second source gas may be a silicon-containing gas.

### TECHNICAL FIELD

The present invention relates to an apparatus and method for processing a substrate, and, more particularly, to an apparatus and method for processing a substrate using plasma.

### BACKGROUND ART

A semiconductor device has a plurality of layers on a silicon substrate. The layers are deposited on the substrate through a deposition process. The deposition process has several important issues, which are important in evaluating deposited films and selecting a deposition method.

One of the important issues is quality of the deposited films. The quality includes composition, contamination level, defect density, and mechanical and electrical properties. The composition of films may change depending upon deposition conditions, which is very important in obtaining a specific composition.

Another important issue is uniform thickness over a wafer. In particular, the thickness of a film deposited at the top of a nonplanar pattern having a step is very important. Whether the thickness of the deposited film is uniform or not may be determined by a step coverage defined as a value obtained by dividing the minimum thickness of the film deposited at the step part by the thickness of the film deposited at the top of the pattern.

Another issue related to the deposition is space filling, which includes gap filling to fill gaps defined between metal lines with an insulation film including an oxide film. The gaps are provided to physically and electrically insulate the metal lines.

Among the above-described issues, the uniformity is one of the important issues related to the deposition process. A nonuniform film causes high electrical resistance on the metal lines, which increases a possibility of mechanical breakage.

### DISCLOSURE OF INVENTION

### Technical Problem

It is an object of the present invention to provide an apparatus and method for processing a substrate that is capable of securing process uniformity.

It is another object of the present invention to provide an apparatus and method for processing a substrate that is capable of securing excellent step coverage.

Other objects of the invention will become more apparent from the following detailed description of the present invention and the accompanying drawings.

### Technical Solution

In accordance with one aspect of the present invention, a substrate processing apparatus includes a chamber defining a process space where a process is carried out with respect to a substrate, a first supply member located above the process space for supplying a first source gas toward the process space, a plasma source configured to generate an electric field in the process space to create radicals from the first source gas, and a second supply member configured to supply a second source gas above the substrate.

The chamber may includes a lower chamber in which a support member configured to allow the substrate to be placed thereon is installed, the lower chamber being open at a top thereof, and the second supply member may be installed at an upper end of the lower chamber for supplying the second source gas in a direction generally parallel to the substrate placed on the support member.

The second source gas may include a silicon-containing gas.

The chamber may include a lower chamber open at a top thereof and an upper chamber configured to open and close the top of the lower chamber, the first supply member may include a spray plate installed at a ceiling of the upper chamber opposite to the process space for supplying the first source gas downward toward the process space, and a buffer space may be defined between the spray plate and the ceiling of the upper chamber.

The first source gas may include nitrous oxide (N₂O) or ammonia (NH₃).

The chamber may include a lower chamber open at a top thereof and an upper chamber configured to open and close the top of the lower chamber, and the plasma source may be disposed to wrap the upper chamber.

The plasma source may include a first segment and a second segment configured to wrap a side of the upper chamber, and the first and second segments may be alternately disposed from one end to the other end of the upper chamber.

The substrate processing apparatus may further include a first power source connected to the first segment for supplying a first electric current to the first segment and a second power source connected to the second segment for supplying a second electric current to the second segment.

The substrate processing apparatus may further include a diffusion plate configured to diffuse the radicals toward the second source gas.

The diffusion plate may partition the process space into a first process space into which the first source gas is supplied to create the radicals and a second process space into which the second source gas is supplied.

The chamber may include a lower chamber in which a support member configured to allow the substrate to be placed thereon is installed, the lower chamber being open at a top thereof, and an upper chamber configured to open and close the top of the lower chamber, the first supply member may include a spray plate installed at one side of the diffusion plate for supplying the first source gas toward the process space, and the second supply member may be installed at the other side of the diffusion plate for supplying the second source gas in a direction generally parallel to the substrate placed on the support member.

The substrate processing apparatus may further include a first supply line connected to the first supply member for supplying the first source gas and a cleaning unit connected to the first supply line for supplying cleaning plasma.

The cleaning unit may include a generation chamber configured to receive a cleaning gas from an outside and to generate cleaning plasma from the cleaning gas and a third supply line connected between the generation chamber and the first supply line for supplying the cleaning plasma to the first supply line.

The cleaning gas may include nitrogen trifluoride (NF₃) or argon (Ar).

The substrate processing apparatus may further include a diffusion plate disposed below the second supply member for diffusing the radicals and the second source gas toward the substrate.

In accordance with another aspect of the present invention, a substrate processing method includes supplying a first source gas toward a process space defined in a chamber, generating an electric field in the process space to create radicals from the first source gas, and supplying a second source gas above a substrate placed in the process space.

The second source gas may be supplied in a direction generally parallel to the substrate.

The substrate processing method may further include diffusing the radicals toward the second source gas using a diffusion plate.

### ADVANTAGEOUS EFFECTS

According to the present invention, it is possible to secure excellent step coverage.

### BRIEF DESCRIPTION OF DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a view schematically illustrating a substrate processing apparatus according to an embodiment of the present invention;

FIG. 2 is a plan view illustrating a lower chamber and a supply nozzle of FIG. 1;

FIG. 3 is a view illustrating the bottom of a spray plate of FIG. 1;

FIG. 4 is a view schematically illustrating a substrate processing apparatus according to another embodiment of the present invention;

FIG. 5 is a view schematically illustrating a substrate processing apparatus according to another embodiment of the present invention;

FIG. 6 is a view schematically illustrating a substrate processing apparatus according to another embodiment of the present invention; and

FIG. 7 is a view schematically illustrating a substrate processing apparatus according to a further embodiment of the present invention.

### BEST MODE FOR CARRYING OUT THE INVENTION

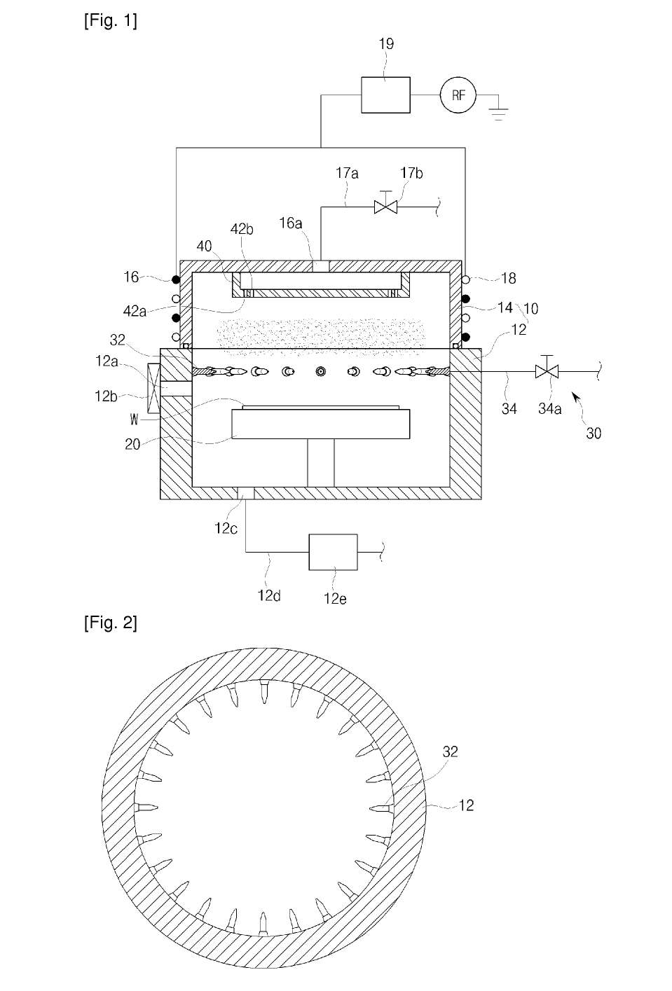

Hereinafter, exemplary embodiments of the present invention will be described in more detail with reference to the accompanying drawings, i.e., FIGS. 1 to 7. Embodiments of the present invention may be modified in various forms, and therefore, the scope of the present invention should not be interpreted to be limited by embodiments which will be described in the following. The embodiments are provided to more clearly describe the present invention to a person having ordinary skill in the art to which the present invention pertains. Consequently, the shape of constituent elements illustrated in the drawings may be exaggerated for a more clear description.

Meanwhile, an inductively coupled plasma (ICP) type plasma process will be described hereinafter as an example, although the present invention is applicable to various plasma processes. Also, a substrate will be described hereinafter as an example, although the present invention is applicable to various objects to be processed.

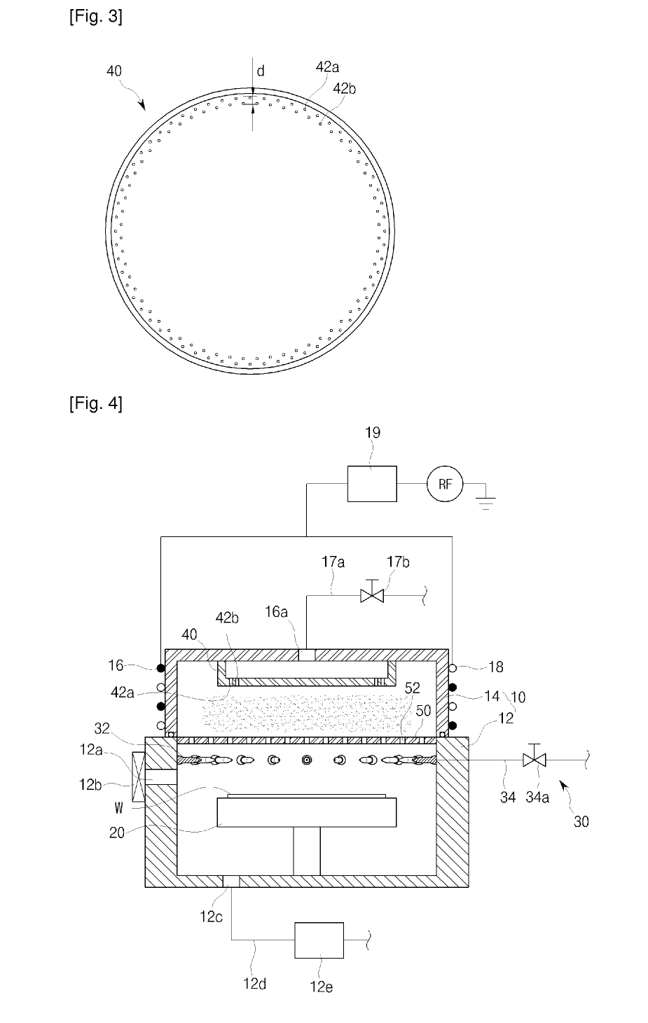

FIG. 1 is a view schematically illustrating a substrate processing apparatus according to an embodiment of the present invention. FIG. 2 is a plan view illustrating a lower chamber and a supply nozzle of FIG. 1, and FIG. 3 is a view illustrating the bottom of a spray plate of FIG. 1.

The substrate processing apparatus includes a chamber 10 defining a process space where a process is carried out with respect to a substrate W. The chamber 10 includes a lower chamber 12 open at the top thereof and an upper chamber 14 configured to close the open top of the lower chamber 12. In the lower chamber 12, a process is carried out with respect to the substrate W. In the upper chamber 14, radicals are generated from a first source gas, which will be described hereinafter.

In the lower chamber 12 is installed a support plate 20. The substrate W is placed on the support plate 20. The substrate W is introduced into the lower chamber 12 through an inlet port 12a formed at one side of the lower chamber 12. The introduced substrate W is placed on the support plate 20. The support plate 20 may be an electrostatic chuck (E-chuck). Also, helium (He) of a predetermined pressure may be sprayed to the rear of the substrate W to accurately control the temperature of the substrate W placed on the support plate 20. The helium exhibits very high thermal conductivity.

At the bottom of the lower chamber 12 is formed an exhaust port 12c. A process gas and reaction by-product are discharged to the outside through an exhaust line 12d connected to the exhaust port 12c. On the exhaust line 12d is installed a pump 12e to forcibly discharge the reaction by-product. Meanwhile, it is possible to reduce the internal pressure of the chamber 10 to a predetermined degree of vacuum through the exhaust port 12c. At the sidewall of the lower chamber 12 is installed a gate valve 12b to open and close the inlet port 12a through which the substrate W is introduced into or removed from the lower chamber 12.

As shown in FIGS. 1 and 3, a spray plate 40 is installed at the ceiling of the upper chamber 14 opposite to the process space. The spray plate 40 is disposed generally in parallel to the substrate W placed on the support plate 20. The spray plate 40 is spaced a predetermined distance from the ceiling of the upper chamber 14 such that a buffer space is defined between the spray plate 40 and the ceiling of the upper chamber 14. At the ceiling of the upper chamber 14 is formed a supply hole 16a. The supply hole 16a is connected to a first supply line 17a. The first supply line 17a supplies a first source gas. The first source gas is supplied into the buffer space through the supply hole 16a. The first source gas supplied into the buffer space is sprayed into the process space through spray holes 42a and 42b formed at the spray plate 40. The first supply line 17a is opened and closed by a valve 17b.

Plasma sources 16 and 18 are installed at the outer circumference of the upper chamber 14. The plasma sources 16 and 18 are disposed in such a manner that the plasma sources 16 and 18 wrap the side of the upper chamber 14. The plasma sources 16 and 18 include a first segment 16 and a second segment 18. The first and second segments 16 and 18 are connected to a radio frequency (RF) generator. Between the first and second segments 16 and 18 and the RF generator is connected a matching unit 19 for impedance matching. The first and second segments 16 and 18 are alternately disposed from the upper end of the upper chamber 14 to the lower end of the upper chamber 14 such that a more uniform electric field is generated in the upper chamber 14.

Radio-frequency current generated from the RF generator is supplied to the first and second segments 16 and 18. The first and second segments 16 and 18 convert the radio-frequency current into a magnetic field, and create radicals from the first source gas supplied into the chamber 10. The first source gas includes nitrous oxide (N₂O) or ammonia (NH₃).

The substrate processing apparatus further includes a supply unit 30. The supply unit 30 includes a supply nozzle 32 installed at the upper end of the lower chamber 12, a second supply line 34 connected to the supply nozzle 32, and a valve 34a configured to open and close the second supply line 34. As shown in FIGS. 1 and 2, the supply nozzle 32 is installed at the upper end of the lower chamber 12 for supplying a second source gas in the direction generally parallel to the substrate W placed on the support plate 20. The second supply line 34 is connected to the supply nozzle 32 for supplying the second source gas to the supply nozzle 32. The second source gas includes a silicon-containing gas, such as silane (SiH₄).

Hereinafter, a substrate processing method according to an embodiment of the present invention will be described in detail with reference to FIGS. 1 to 3. A first source gas, supplied through the first supply line 17a, is supplied into the buffer space defined between the ceiling of the upper chamber 14 and the spray plate 40, and is then supplied into the process space through the spray holes 42a and 42b. The first and second segments 16 and 18, installed at the side of the upper chamber 14, convert radio-frequency current, supplied from the outside, into a magnetic field, and create radicals from the first source gas supplied into the process space. The supply nozzle 32 supplies a second source gas above the substrate W. The second source gas reacts with the radicals to deposit a film on the substrate W.

FIG. 4 is a view schematically illustrating a substrate processing apparatus according to another embodiment of the present invention. Hereinafter, only components of this embodiment distinguished from the previous embodiment shown in FIG. 1 will be described, and the description of omitted components will be understood from the description previously made with reference to FIG. 1.

The substrate processing apparatus further includes a diffusion plate 50 installed at the upper end of the lower chamber 12. The diffusion plate 50 is disposed generally in parallel to the substrate W placed on the support plate 20, and is located above the supply nozzle 32. Above the diffusion plate 50, radicals are created from a first source gas. The created radicals are diffused below the diffusion plate 50 through diffusion holes 52 formed at the diffusion plate 50. Below the diffusion plate 50, a second source gas is sprayed through the supply nozzle 32.

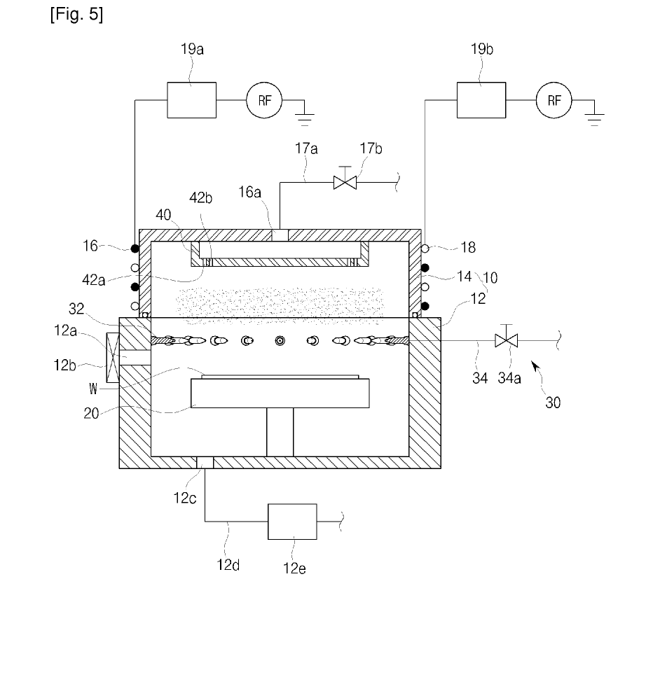

FIG. 5 is a view schematically illustrating a substrate processing apparatus according to another embodiment of the present invention. Hereinafter, only components of this embodiment distinguished from the previous embodiment shown in FIG. 1 will be described, and the description of omitted components will be understood from the description previously made with reference to FIG. 1.

The first and second segments 16 and 18 are connected to different radio frequency (RF) generators, respectively. Between the first and second segments 16 and 18 and the corresponding RF generators are connected matching units 19a and 19b for impedance matching, respectively. The first and second segments 16 and 18 are alternately disposed from the upper end of the upper chamber 14 to the lower end of the upper chamber 14 such that a more uniform electric field is generated in the upper chamber 14.

Since the first and second segments 16 and 18 are connected to the respective RF generators, different kinds of radio-frequency current are supplied to the first and second segments 16 and 18, respectively. Consequently, it is possible to differently adjust the magnitude of the radio-frequency current supplied to the first segment 16 and the magnitude of the radio-frequency current supplied to the second segment 18 by differently controlling the RF generator connected to the first matching unit 19a and the RF generator connected to the second matching unit 19b. As a result, it is possible to control process uniformity with respect to the substrate W placed on the support plate 20.

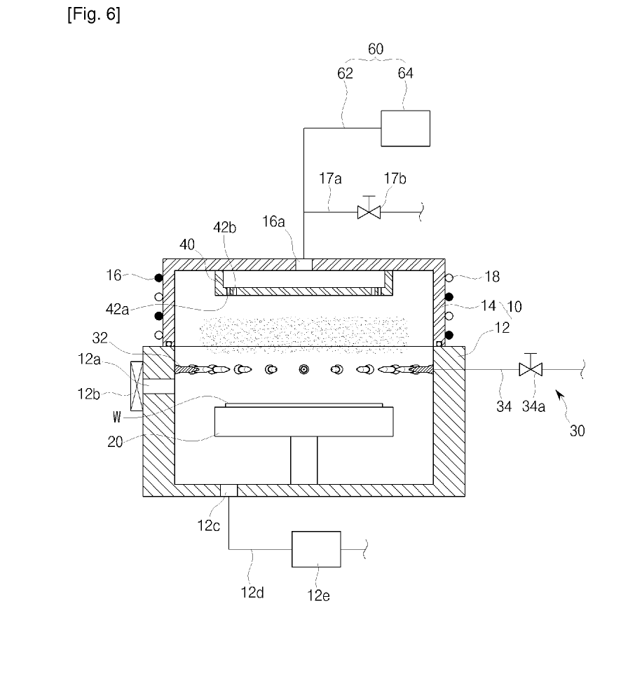

FIG. 6 is a view schematically illustrating a substrate processing apparatus according to another embodiment of the present invention. Hereinafter, only components of this embodiment distinguished from the previous embodiment shown in FIG. 1 will be described, and the description of omitted components will be understood from the description previously made with reference to FIG. 1.

The substrate processing apparatus further includes a cleaning unit 60 to clean the interior of the chamber 10. The cleaning unit 60 includes a third supply line 62 connected to the first supply line 17a and a generation chamber 64 configured to generate cleaning plasma from a cleaning gas supplied from the outside. The cleaning plasma generated in the generation chamber 64 is supplied into the chamber 10 via the third supply line 62 and the first supply line 17a to clean the interior of the chamber 10. The cleaning gas includes nitrogen trifluoride (NF₃) or argon (Ar).

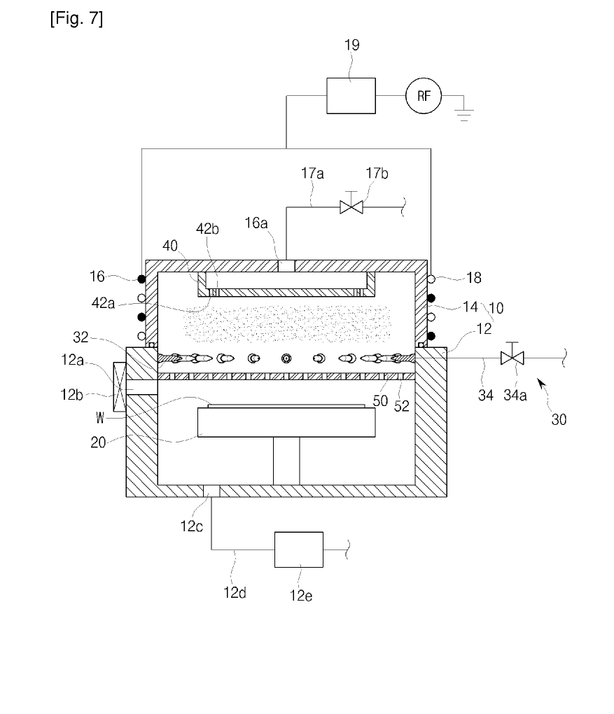

FIG. 7 is a view schematically illustrating a substrate processing apparatus according to a further embodiment of the present invention. Hereinafter, only components of this embodiment distinguished from the previous embodiment shown in FIG. 1 will be described, and the description of omitted components will be understood from the description previously made with reference to FIG. 1.

The substrate processing apparatus further includes a diffusion plate 50 installed below the supply nozzle 32. The diffusion plate 50 is disposed generally in parallel to the substrate W placed on the support plate 20. Above the diffusion plate 50, radicals are created from a first source gas. A second source gas is sprayed from the supply nozzle 32. The second source gas reacts with the created radicals, and, at the same time, is diffused to the substrate W, located below the diffusion plate 50, through diffusion holes 52 formed at the diffusion plate 50.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

### INDUSTRIAL APPLICABILITY

Apparent from the above description, it is possible to secure excellent step coverage. Consequently, the present invention has industrial applicability.

1. A substrate processing apparatus comprising:
a chamber defining a process space where a process is carried out with respect to a substrate;
a first supply member located above the process space for supplying a first source gas toward the process space;
a plasma source configured to generate an electric field in the process space to create radicals from the first source gas; and
a second supply member configured to supply a second source gas above the substrate.

2. The substrate processing apparatus according to claim 1, wherein
the chamber comprises a lower chamber in which a support member configured to allow the substrate to be placed thereon is installed, the lower chamber being open at a top thereof, and
the second supply member is installed at an upper end of the lower chamber for supplying the second source gas in a direction generally parallel to the substrate placed on the support member.

3. The substrate processing apparatus according to claim 1, wherein the second source gas comprises a silicon-containing gas.

4. The substrate processing apparatus according to claim 1, wherein the chamber comprises:
a lower chamber open at a top thereof; and
an upper chamber configured to open and close the top of the lower chamber,
the first supply member comprises a spray plate installed at a ceiling of the upper chamber opposite to the process space for supplying the first source gas downward toward the process space, and
a buffer space is defined between the spray plate and the ceiling of the upper chamber.

5. The substrate processing apparatus according to claim 1, wherein the first source gas comprises nitrous oxide (N₂O) or ammonia (NH₃).

6. The substrate processing apparatus according to claim 1, wherein
the chamber comprises:
a lower chamber open at a top thereof; and
an upper chamber configured to open and close the top of the lower chamber, and
the plasma source is disposed to wrap the upper chamber.

7. The substrate processing apparatus according to claim 6, wherein
the plasma source comprises a first segment and a second segment configured to wrap a side of the upper chamber, and
the first and second segments are alternately disposed from one end to the other end of the upper chamber.

8. The substrate processing apparatus according to claim 7, further comprising:
a first power source connected to the first segment for supplying a first electric current to the first segment; and
a second power source connected to the second segment for supplying a second electric current to the second segment.

9. The substrate processing apparatus according to claim 1, further comprising a diffusion plate configured to diffuse the radicals toward the second source gas.

10. The substrate processing apparatus according to claim 9, wherein the diffusion plate partitions the process space into a first process space into which the first source gas is supplied to create the radicals and a second process space into which the second source gas is supplied.

11. The substrate processing apparatus according to claim 9, wherein
the chamber comprises:
a lower chamber in which a support member configured to allow the substrate to be placed thereon is installed, the lower chamber being open at a top thereof; and
an upper chamber configured to open and close the top of the lower chamber,
the first supply member comprises a spray plate installed at one side of the diffusion plate for supplying the first source gas toward the process space, and
the second supply member is installed at the other side of the diffusion plate for supplying the second source gas in a direction generally parallel to the substrate placed on the support member.

12. The substrate processing apparatus according to claim 1, further comprising:
a first supply line connected to the first supply member for supplying the first source gas; and
a cleaning unit connected to the first supply line for supplying cleaning plasma.

13. The substrate processing apparatus according to claim 12, wherein the cleaning unit comprises:
a generation chamber configured to receive a cleaning gas from an outside and to generate cleaning plasma from the cleaning gas; and
a third supply line connected between the generation chamber and the first supply line for supplying the cleaning plasma to the first supply line.

14. The substrate processing apparatus according to claim 13, wherein the cleaning gas comprises nitrogen trifluoride (NF₃) or argon (Ar).

15. The substrate processing apparatus according to claim 1, further comprising a diffusion plate disposed below the second supply member for diffusing the radicals and the second source gas toward the substrate.

16. A substrate processing method comprising:
supplying a first source gas toward a process space defined in a chamber;
generating an electric field in the process space to create radicals from the first source gas; and
supplying a second source gas above a substrate placed in the process space.

17. The substrate processing method according to claim 16, wherein the second source gas is supplied in a direction generally parallel to the substrate.

18. The substrate processing method according to claim 16, further comprising diffusing the radicals toward the second source gas using a diffusion plate.

19. The substrate processing apparatus according to claim 2, wherein the second source gas comprises a silicon-containing gas.

20. The substrate processing apparatus according to claim 4, wherein the first source gas comprises nitrous oxide (N₂O) or ammonia (NH₃).

21. The substrate processing apparatus according to claim 10, wherein
the chamber comprises:
a lower chamber in which a support member configured to allow the substrate to be placed thereon is installed, the lower chamber being open at a top thereof; and
an upper chamber configured to open and close the top of the lower chamber,
the first supply member comprises a spray plate installed at one side of the diffusion plate for supplying the first source gas toward the process space, and
the second supply member is installed at the other side of the diffusion plate for supplying the second source gas in a direction generally parallel to the substrate placed on the support member.
